(19) United States
(12) Patent Application Publication
(10) Pub. No.: US 2026/0344276 A1
(43) Pub. Date: Oct. 29, 2026

(54) ORGANIC VAPOR JET PRINTING SYSTEM

(71) Applicant: Universal Display Corporation, Ewing, NJ (US)

(72) Inventors: Gregory McGraw, Yardley, PA (US); Michael Hack, Carmel, CA (US); Chandran Ramesh Nair, Singapore (SG)

(21) Appl. No.: 19/660,642

(22) Filed: Apr. 28, 2026

Related U.S. Application Data
(60) Provisional application No. 63/796,872, filed on Apr. 29, 2025.

(51) Int. Cl. H10K 71/16; G02B 6/12; G02B 6/13; H10K 50/858

(52) U.S. Cl. CPC H10K 71/16; G02B 6/12004; G02B 6/13; H10K 50/858

(57) ABSTRACT

Embodiments of the disclosed subject matter provide a photonic integrated circuit comprising an organic light emitting diode (OLED) and a waveguide in optical contact with the OLED. Embodiments of the disclosed subject matter provide a photonic integrated circuit further comprising a downconverter. Embodiments of the disclosed subject matter provide a method for fabricating a photonic integrated circuit wherein the waveguide is formed by polymerization of one or more vaporized precursor species deposited on the substrate.

### CROSS-REFERENCES TO RELATED APPLICATIONS

This application claims priority under 35 U.S.C. § 119(e) to U.S. Provisional Application No. 63/796,872, filed on Apr. 29, 2025, and the entire contents of the above referenced application are incorporated herein by reference.

### FIELD

The present invention relates to devices and techniques for fabricating organic emissive devices, such as organic light emitting devices, including systems and methos for making an OLED in optical communication with a polymer waveguide deposited from the vacuum phase for optical transmission of data, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more devices selected from a consumer product, an electronic component module, and/or a lighting panel.

According to an embodiment, a photonic integrated circuit is provided that includes an organic light emitting diode (OLED) and a waveguide in optical contact with the OLED.

In an embodiment, the waveguide comprises polymer.

In an embodiment, the photonic integrated circuit further comprises a downconverter film, wherein the downconverter film absorbs light emitted by the OLED and re-emits light at a lower wavelength.

A method for fabricating a photonic integrated circuit comprising an organic light emitting diode (OLED) and a waveguide in optical contact with the OLED is provided.

In an embodiment, the polymer is formed by in situ polymerization of one or more vaporized monomer precursors.

In an embodiment, the polymer is formed from the condensation of two or more reacting monomers.

In an embodiment, the polymer is formed from free radical polymerization of a vaporized monomer.

In an embodiment, the polymer is formed from one or more condensed materials deposited from the vapor phase that undergo polymerization after deposition.

In an embodiment, one or more precursor materials are dispensed using one or more delivery apertures in a micronozzle array.

In an embodiment, surplus precursor is removed using exhaust apertures in a micronozzle array.

In an embodiment, the flow of confinement gas moving antiparallel to the flow from the delivery apertures limits the spatial extent of precursor deposition.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a schematic representation of a photonic integrated circuit including an OLED and a waveguide structure according to embodiments of the disclosed subject matter.

FIG. 4 shows an OLED, waveguide structure and downconverter according to embodiments of the disclosed subject matter.

FIG. 5 shows a DEC device for dispensing precursors for iCVD or other polymer deposition processes according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6(1999) (“Baldo-II”), are incorporated by reference in their entireties. Phosphorescence is described in more detail in U.S. Pat. No. 7,279,704 at cols. 5-6, which are incorporated by reference.

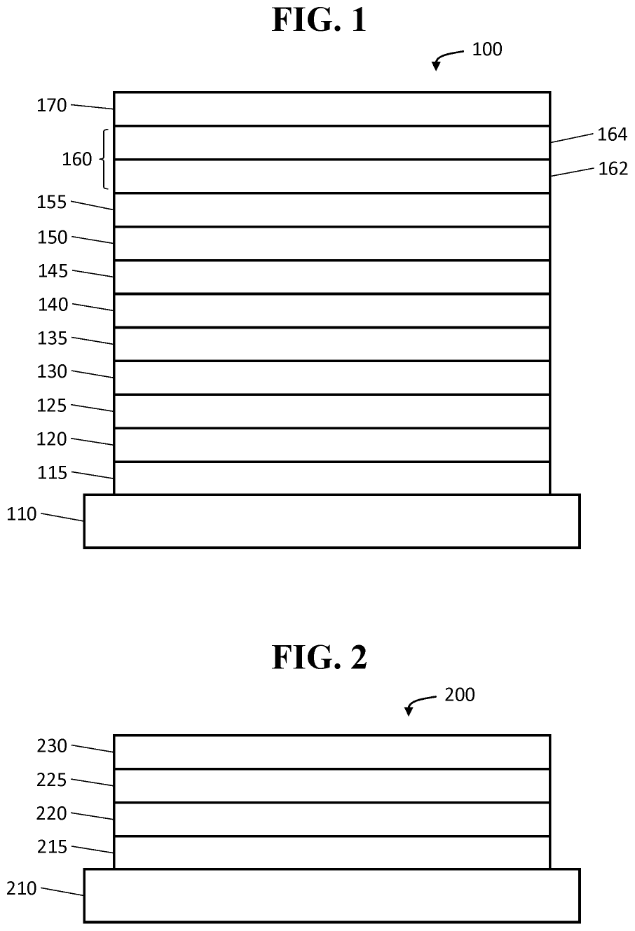

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

As previously disclosed, one type of technique for fabricating OLEDs and similar devices is OVJP, a maskless, solventless approach to printing large area OLED displays. In OVJP, narrow lines of OLED material are printed on the display backplane using a series of apertures formed in a silicon die, which may be manufactured using Microelectromechanical systems (MEMS) technology. Specific examples of OVJP systems are disclosed in U.S. Pat. Nos. 10,170,701 and 11,267,012, the disclosure of each of which is incorporated by reference in its entirety, and U.S. Application Publication Nos. 2019/0221783 and 2019/0218655, the disclosure of each of which is incorporated by reference in its entirety.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Photonic integrated circuits (PICs) offer a promising approach for rapid data transmission and processing. Many of the materials required to make PICs are not CMOS compatible, so new fabrication techniques are required to make them. A preferred example of such a technique is the use of OLEDs added to existing integrated circuits by vapor deposition or the like. No additional high temperature or solvent processing steps are required, making them an attractive option for a PIC light source. Most PICs today use coherent laser light as the source of photons for processing. In many cases OLEDs can be used as the source of optical excitation. They can emit visible light or, if O-band or C-band NIR is required, the OLED light can be downconverted. The OLED emission, or downconverted OLED emission, may be bottom or top emission, and the light emitted by the OLED may enter the waveguide either from its top or bottom surface.

Previously, OLEDs were considered to be poorly suited for use in PICs because most conventional PICs have used near infrared light in the O and/or C bands, regions in which OLEDs have traditionally performed less efficiently than other options. Earlier OLEDs also were considered to be too inefficient and lacking in sufficient luminance. It has recently been determined that advances in OLED materials, fabrication, and capability, including efficiency and luminance, allow for use of OLEDs in PICs. Further, OLEDs may be tailed for specific wavelengths, for example through use of a downconversion component to achieve near infrared emission as disclosed herein. Recent advancements in OLED technology, coupled with the use UVJP techniques as disclosed herein to fabricate waveguides on a common substrate with OLEDs, renders OLEDs suitable for use in PICs.

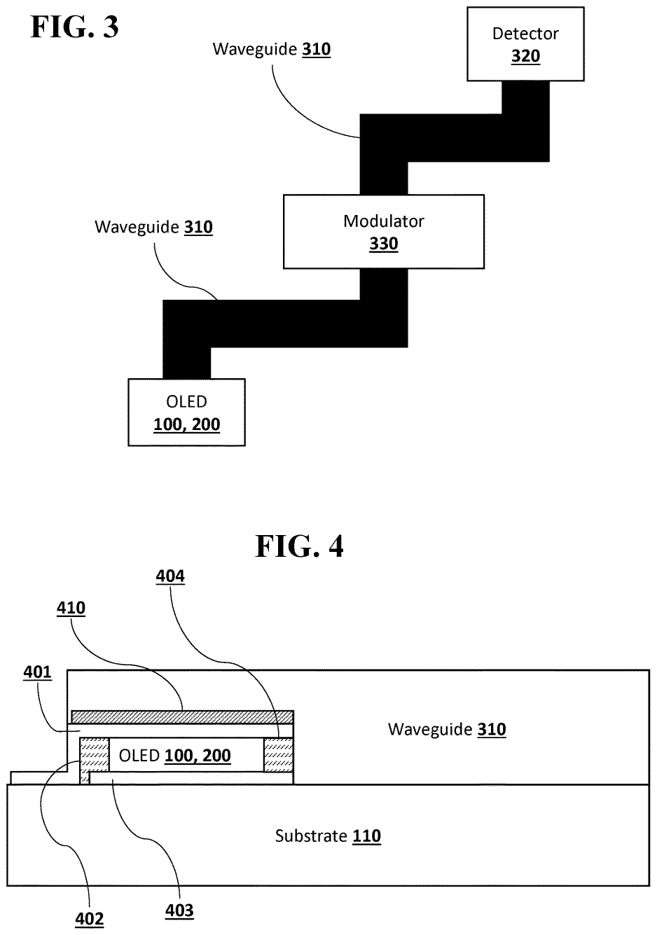

FIG. 3 shows a schematic representation of a PIC including an OLED and polymer waveguide as disclosed herein. The OLED 100, 200 may have a general structure and composition as previously disclosed with respect to FIGS. 1 and 2, though other similar structures and known OLED components may be used. The OLED 100, 200 may be in optical communication with other circuit components such as a modulator 330, detector 320, and the like. These components may operate in the same manner as in a conventional PIC. One or more waveguides 310 may connect the OLED 100, 200 to the other components 310, 320 to allow for data to be communicated through the PIC.

The OLED and waveguide may be fabricated as a single component, and may be deposited on a common substrate using similar techniques as disclosed in further detail herein. Alternatively, a waveguide such as a polymer waveguide as disclosed herein may be fabricated on a substrate on which the OLED is already present.

FIG. 4 shows an example of a PIC component that includes an OLED 100, 200 and a waveguide structure 310. In FIG. 4, structure 401 is an electrode such as a cathode of the OLED. Structures 402 and 404 are both pixel defining layers (PDLs), which are used to define the active areas of each pixel and subpixel. structure 403 is an electrode such as anode of the OLED. A downconverter film, layer, or other structure 410 may be included, for example to convert visible or near infra-red light generated by the OLED into longer wavelength IR light better suited to the PIC application. The downconverter 410 may be optically disposed between the OLED 100, 200 and the waveguide 310, and may be in direct physical contact with one or both of the OLED and/or the waveguide. The OLED 100, 200 may provide the light and/or excitation source for the PIC, which may be converted to a required wavelength region via the downconverter 410 and conveyed to other components of the PIC via the waveguide structure 310.

In some embodiments, the OLED may be fully embedded/covered in the waveguide. In some embodiments, the OLED may be partially covered by the waveguide. For example, one or more sides of the OLED and/or some or all of an upper surface of the OLED may be covered by the waveguide. In some embodiments, the top and one side of the OLED may be covered by the waveguide. In some embodiments, all but the substrate sides of the OLED are in direct contact with the waveguide. More generally, the waveguide is positioned so that at least a portion of light emitted by the OLED will enter the waveguide and be transmitted through the waveguide to other components of a PIC, such as a modulator 330 as shown in FIG. 3. At least a portion of the waveguide may be in direct physical contact with at least a portion of the OLED, or the OLED and waveguide may be physically separated but in optical communication such that light emitted by the OLED enters the waveguide, either directly or via an intervening component that similarly transfers the generated light to the waveguide.

In embodiments that include a capping layer or downconversion layer over the OLED, the capping layer or downconversion layer is in direct contact with the waveguide. In some embodiments, the downconversion layer may be used to convert light into NIR in the range of 700 to 2500 nm. In some embodiments, the downconversion may be used to convert light into the O-band region in the wavelength ranging from 1260 to 1360 nm. In some embodiments, the downconversion may be used to convert light into the C-band region in the wavelength ranging from 1530-1565 nm.

As previously described, OLEDs may be fabricated using OVJP systems and techniques. As disclosed herein, it has also been found that universal vapor jet printing (UVJP), an adaptation of OVJP, may be used to perform chemical vapor deposition (CVD)-type fabrication of components, such as precursor materials for polymer waveguides for use in PICs in combination with OLEDs. As with OVJP for OLEDs, UVJP permits waveguides of very well controlled and reproducible thickness to be deposited. UVJP does this without introducing solvents and their related complications. For example, a UVJP system may be similar, equivalent, or identical to an OVJP system used to fabricate OLEDs, but may eject polymer precursors instead of emissive materials and other materials used in OLED fabrication, to fabricate a polymeric waveguide for use in a PIC. The route of a waveguide can also be patterned on-demand by UVJP by moving the print head and substrate relative to each other to draw it. This is achieved without the use of shadow masks. Examples of OVJP systems and techniques that may be adapted for UVJP are disclosed in, for example, U.S. Pat. Nos. 11,267,012 and 10,170,701, the disclosure of each of which is incorporated by reference in its entirety. Such systems and techniques may be used to perform UVJP deposition of waveguides as disclosed herein by using appropriate precursors and other materials to deposit the polymer waveguides.

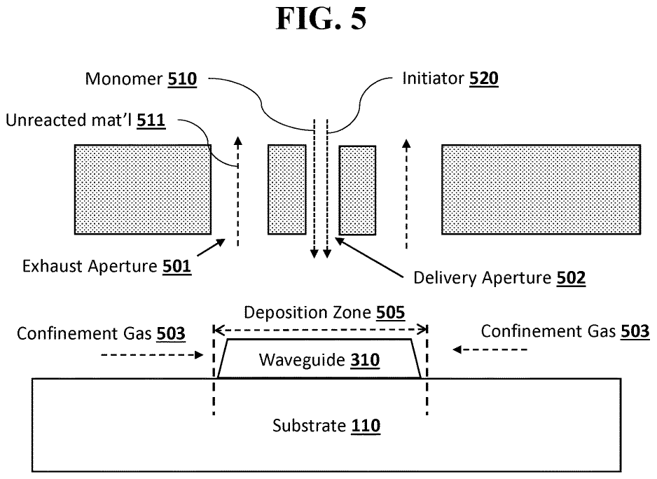

An OVJP techniques applied to deposition of a polymer precursor or similar material are referred to herein as a “UVJP technique.” For example, UVJP techniques include ejection of a polymer precursor through an OVJP-style nozzle block as disclosed in the patents and publications incorporated by reference herein. as a specific example, convective control of the deposition zone may be used to print fine features of the waveguide. One example to do so is a delivery-exhaust-confinement (DEC) nozzle block and deposition process, such as described in U.S. Pat. No. 11,267,012, the disclosure of which is incorporated by reference in its entirety. A DEC system and process may be modified to dispense precursors for iCVD or other polymer deposition process as shown in FIG. 5. Monomer resin 510 and initiator 520 are fed into a print head that is heated to activate the initiator. The materials are ejected toward the substrate 110 through a heated delivery aperture 502 and condense on a cold substrate 110. Unreacted material 511, such as unpolymerized surplus precursor material 510, 520 is drawn up into exhaust apertures 501 for disposal or reuse. The spread of material outside the intended deposition zone 505 may be blocked by a counterflow of confinement gas 503, flowing antiparallel to the flow of material through the delivery aperture(s) 502.

The disclosed process involves growing a polymer waveguide on a substrate from one or more vaporized monomer precursors. The polymer may be formed, for example, via in situ polymerization of the vaporized precursors on the substrate. The polymer may be formed after the monomers and/or other precursors condense on the substrate and subsequently undergo polymerization. The polymerization may be a condensation reaction between two alternating species of monomer. Alternatively, it may be a free radical polymerization in which a single vaporized monomer is combined with a small amount of thermally activated initiator such as in the iCVD process. Many other possible deposition chemistries exist. Precursors deposited from vapor also need not react immediately. They may, for example, polymerize during a post-deposition bake or upon exposure to UV light.

In some embodiments, an OLED on a substrate may be used for growing a polymer waveguide on the substrate. In such embodiments, the OLED on the substrate may be made by methods known in the art. The present disclosure thus also discloses a method of making a photonic integrated circuit by providing or obtaining an OLED in a substrate, depositing one or more polymer precursors on the substrate from a vapor source; and polymerizing the one or more polymer precursors to form a waveguide on the substrate and in optical communication with the OLED.

In another aspect, the present disclosure provides also an organic light emitting diode (OLED) device, comprising:
(a) a first electrode;
(b) a second electrode;
(c) an organic emissive stack disposed between the first electrode and the second electrode and configured to emit first light having a first emission spectrum; and
(d) a color altering layer positioned to receive at least a portion of the first light, wherein the color altering layer is configured to convert at least a portion of the first light into second light having an emission spectrum including a wavelength component greater than or equal to 800 nm.

In some embodiments, the color altering layer is configured such that the second light includes a wavelength component greater than or equal to 1000 nm. In some embodiments, the color altering layer is configured such that the second light includes a wavelength component greater than or equal to 1300 nm. In some embodiments, the color altering layer is configured such that the second light includes a wavelength component greater than or equal to 1500 nm.

In some embodiments, the color altering layer comprises a photoluminescent material that emits the second light in response to optical excitation by the first light.

In some embodiments, the color altering layer exhibits a Stokes shift such that a peak wavelength of the second light is longer than a peak wavelength of the first light by at least 50 nm.

In some embodiments, the second light includes a spectral peak within 800-1100 nm, 1000-1400 nm, or 1300-1700 nm.

In some embodiments, the color altering layer converts at least 10% of optical power of the first light incident on the color altering layer into the second light.

In some embodiments, the second light has a full width at half maximum (FWHM) of less than 100 nm, less than 50 nm, less than 30 nm, or less than 10 nm.

In some embodiments, the color altering layer is disposed outside the organic emissive stack.

In some embodiments, the color altering layer is disposed on an outcoupling side of the OLED device.

In some embodiments, the color altering layer is disposed between the OLED device and an encapsulation layer.

In some embodiments, the color altering layer is disposed on a separate substrate positioned adjacent to the OLED device.

In some embodiments, the OLED further comprises an optical spacer between the organic emissive stack and the color altering layer.

In some embodiments, the color altering layer comprises nonlinear crystal material.

In some embodiments, the color altering layer comprises one or more of: semiconductor nanocrystals, rare-earth doped particles, organic fluorescent dyes, organometallic complexes, perovskite materials, or phosphors dispersed in a matrix.

In some embodiments, the color altering layer comprises a rare-earth emitter including at least one of erbium, ytterbium, neodymium, thulium, holmium, or praseodymium.

In some embodiments, the color altering layer comprises an erbium-containing emitter and the second light includes a wavelength component of about 1.5 micrometers.

In some embodiments, the color altering layer comprises a neodymium-containing emitter and the second light includes a wavelength component of about 1.06 micrometers or about 1.3 micrometers.

In some embodiments, the color altering layer comprises a host matrix including a polymer, inorganic oxide, sol-gel, glass, or hybrid organic-inorganic material.

In some embodiments, the color altering layer further comprises scattering particles or refractive-index modifying particles.

In some embodiments, the first light comprises blue light having a peak wavelength in a range of 400-500 nm. In some embodiments, the first light comprises green light having a peak wavelength in a range of 500-570 nm. In some embodiments, the first light comprises red light having a peak wavelength in a range of 600-700 nm.

In some embodiments, the organic emissive stack comprises a microcavity structure configured to increase emission toward the color altering layer.

In some embodiments, the device is configured as an infrared emitter for biometric sensing, proximity sensing, time-of-flight sensing, spectroscopy, communications, or medical monitoring.

In some embodiments, the second light includes a wavelength component within an optical telecommunications band including O-band (about 1260-1360 nm) or C-band (about 1530-1565 nm).

In some embodiments, the OLED further comprises an optical filter configured to reduce transmission of at least a portion of the first light while transmitting at least a portion of the second light.

In some embodiments, the above device may further comprise a waveguide. In such embodiments, the waveguide is in optical communication with the device to transmit information. In such embodiments, all those OLED photonic integrated circuit related embodiments may be equally applied here.

In yet another aspect, the present disclosure also provides a method of making an OLED device, the method comprising: depositing a first electrode over a substrate; depositing an organic emissive stack over the first electrode, depositing a second electrode over the organic emissive stack; and depositing a color altering layer over the second electrode. The depositing may be performed by an OVJP method or other methods as disclosed or referenced herein.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
a photonic integrated circuit comprising:
an organic light emitting diode (OLED); and
a first waveguide in optical communication with the OLED.

2. The device of claim 1, wherein the first waveguide comprises a polymer.

3. The device of claim 1, further comprising a downconverter optically disposed between the OLED and the first waveguide, such that light emitted by the OLED is downconverted prior to entering the first waveguide.

4. The device of claim 1, further comprising a modulator in optical communication with the first waveguide.

5. The device of claim, further comprising a detector in optical communication with the modulator.

6. The device of claim, further comprising a second waveguide disposed between the detector and the modulator.

7. The device of claim, wherein the second waveguide comprises a polymer.

8. A method comprising:
fabricating a photonic integrated circuit by:
obtaining an OLED on a substrate;
depositing one or more polymer precursors on the substrate from a vapor source; and
polymerizing the one or more polymer precursors to form a waveguide on the substrate and in optical communication with the OLED.

9. The method of claim, wherein the step of depositing the one or more polymer precursors is performed using a universal vapor jet printing (UVJP) technique.

10. The method of claim, wherein the UVJP technique comprises ejecting the one or more polymer precursors from one or more delivery apertures in a micronozzle array.

11. The method of claim, wherein the UVJP technique comprises removing unpolymerized surplus precursor via one or more exhaust apertures in the micronozzle array.

12. The method of claim, wherein the UVJP technique further comprises providing a flow of confinement gas to limit spread of the one or more precursors beyond an intended deposition region on the substrate.

13. The method of claim, wherein the one or more precursors comprise vaporized monomer precursors and the polymer is formed via in situ polymerization of the vaporized monomer precursors.

14. The method of claim, wherein the one or more precursors comprise vaporized monomer precursors and the polymer is formed via condensation and reaction of the vaporized monomer precursors.

15. The method of claim, wherein the one or more precursors comprise a vaporized monomer and the polymer is formed from free radical polymerization of the vaporized monomer.

16. The method of claim, wherein the polymer is formed from condensation of one or more condensed materials that undergo polymerization after deposition.

17. An organic light emitting diode (OLED) device, comprising:
(a) a first electrode;
(b) a second electrode;
(c) an organic emissive stack disposed between the first electrode and the second electrode and configured to emit first light having a first emission spectrum; and
(d) a color altering layer positioned to receive at least a portion of the first light, wherein the color altering layer is configured to convert at least a portion of the first light into second light having an emission spectrum including a wavelength component greater than or equal to 800 nm.

18. The OLED device of claim 17, wherein the color altering layer is configured such that the second light includes a wavelength component greater than or equal to 1000 nm.

19. The OLED device of claim 17, wherein the color altering layer is configured such that the second light includes a wavelength component greater than or equal to 1300 nm.

20. The OLED device of claim 17, wherein the color altering layer is configured such that the second light includes a wavelength component greater than or equal to 1500 nm.

21-45. (canceled)
